(19) United States
(12) Patent Application Publication
(10) Pub. No.: US 2019/0198633 A1
(43) Pub. Date: Jun. 27, 2019

(54) SEMICONDUCTOR STRUCTURE AND METHOD FOR FORMING THE SAME

(71) Applicant: Vanguard International Semiconductor Corporation, Hsinchu (TW)

(72) Inventors: Shih-Chieh CHIEN, Nantou City (TW); Manoj KUMAR, Dhanbad (IN); Chia-Hao LEE, New Taipei City (TW); Chih-Cherng LIAO, Jhudong Township (TW)

(73) Assignee: Vanguard International Semiconductor Corporation, Hsinchu (TW)

(21) Appl. No.: 15/852,213

(22) Filed: Dec. 22, 2017

(51) Int. Cl. H01L 29/423; H01L 29/06; H01L 21/266; H01L 21/28; H01L 29/78; H01L 29/66; H01L 21/265

(52) U.S. Cl. CPC H01L 29/42368; H01L 29/063; H01L 29/4236; H01L 21/266; H01L 29/1087; H01L 21/28238; H01L 29/7813; H01L 29/66734; H01L 21/26513; H01L 21/28211

(57) ABSTRACT

A semiconductor structure is provided. The semiconductor structure includes a semiconductor substrate, a gate trench in the semiconductor substrate, a gate dielectric layer disposed on sidewalls of the gate trench, a gate trench extending portion under the gate trench, an insulating stud disposed in the gate trench extending portion, a gate electrode disposed in the gate trench and on the insulting stud, a doping well region embedded in the semiconductor substrate at opposite sides of the gate trench, and a source region disposed on the doping well region in the semiconductor substrate.

### BACKGROUND

Embodiments of the present disclosure relate to a semiconductor structure, and in particular they relate to a power metal-oxide-semiconductor field-effect transistor (power MOSFET).

Semiconductor structures are used in a variety of electronic applications, such as personal computers, cell phones, digital cameras, and other electronic devices. These semiconductor structures are typically fabricated by depositing an insulating layer or dielectric layer, a conductive layer material, and a semiconductor layer material on the semiconductor substrate, followed by patterning the various material layers by using a photolithography process. Therefore, the circuit devices and components are formed on the semiconductor substrate.

Among these devices, power metal-oxide-semiconductor field-effect transistors have been widely used in the field of analog circuits and digital circuits. Since power metal-oxide-semiconductor field-effect transistors have advantages such as low input power loss and high switching speed, they are promising in the field of power devices.

One of the most important properties of the power metal-oxide-semiconductor field-effect transistor is its breakdown voltage. However, using existing techniques to increase the breakdown voltage may result in an increase of the on-resistance and threshold voltage of the transistor, which may be disadvantageous to device operation. Therefore, existing power metal-oxide-semiconductor field-effect transistors still have many problems to be solved.

### SUMMARY

Some embodiments of the present disclosure relate to a semiconductor structure. The semiconductor structure includes a semiconductor substrate, a gate trench in the semiconductor substrate, a gate dielectric layer disposed on sidewalls of the gate trench, a gate trench extending portion under the gate trench, an insulating stud disposed in the gate trench extending portion, a gate electrode disposed in the gate trench and on the insulating stud, a doping well region embedded in the semiconductor substrate at opposite sides of the gate trench, and a source region disposed on the doping well region in the semiconductor substrate.

Some embodiments of the present disclosure relate to a method of forming a semiconductor structure. The method includes providing a semiconductor substrate, forming a gate trench in the semiconductor substrate, forming a gate dielectric layer on sidewalls of the gate trench, recessing the gate trench to form a gate trench extending portion under the gate trench, forming an insulating stud in the gate trench extending portion, forming a gate electrode in the gate trench and on the insulating stud, forming a doping well region in the semiconductor substrate at opposite sides of the gate trench, and forming a source region on the doping well region in the semiconductor substrate.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, 1F, 1G, 1H, 1I, 1J, 1K, and 1L are a series of cross-sectional views illustrating a method of forming a semiconductor structure according to some embodiments of the present disclosure.

FIGS. 2-3 are cross-sectional views of some semiconductor structures according to other embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

It should be understood that additional steps can be implemented before, during, or after the illustrated methods, and some steps might be replaced or omitted in other embodiments of the illustrated methods.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The semiconductor structure of the present disclosure includes a gate trench extending portion under a gate trench, and an insulating stud formed in the gate trench extending portion. The insulating stud may increase the breakdown voltage while maintaining low on-resistance and low threshold voltage of the semiconductor structure.

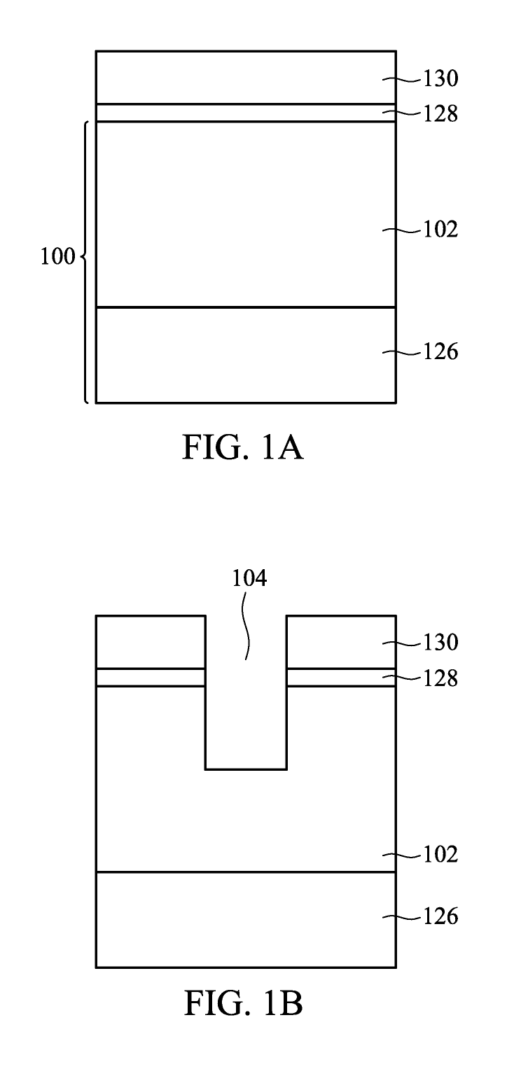

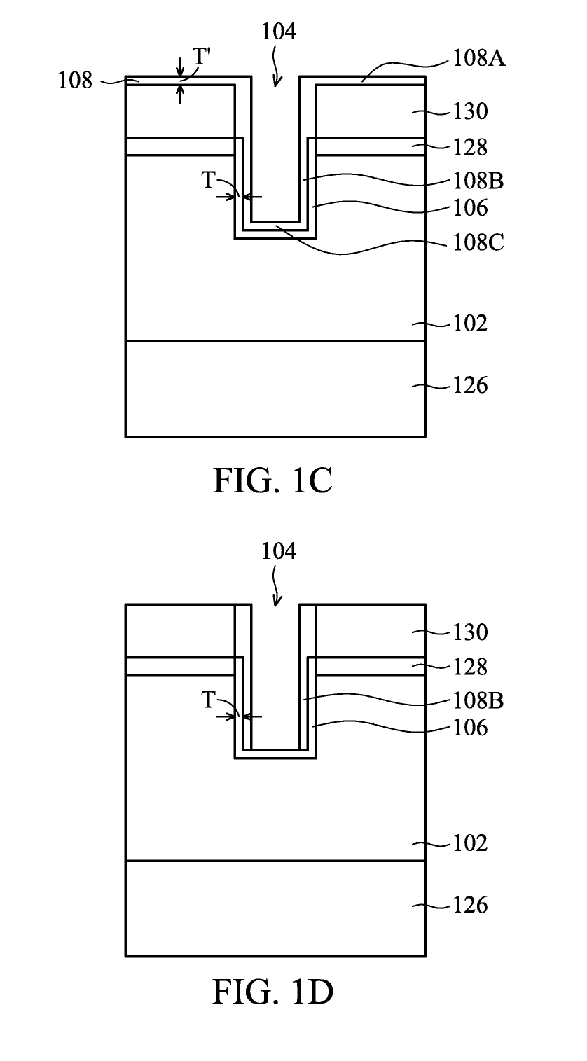

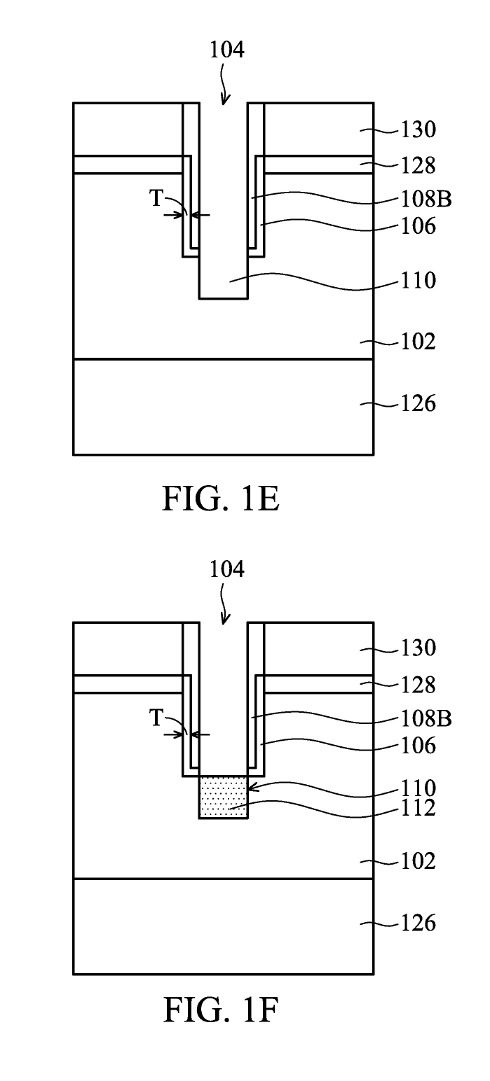

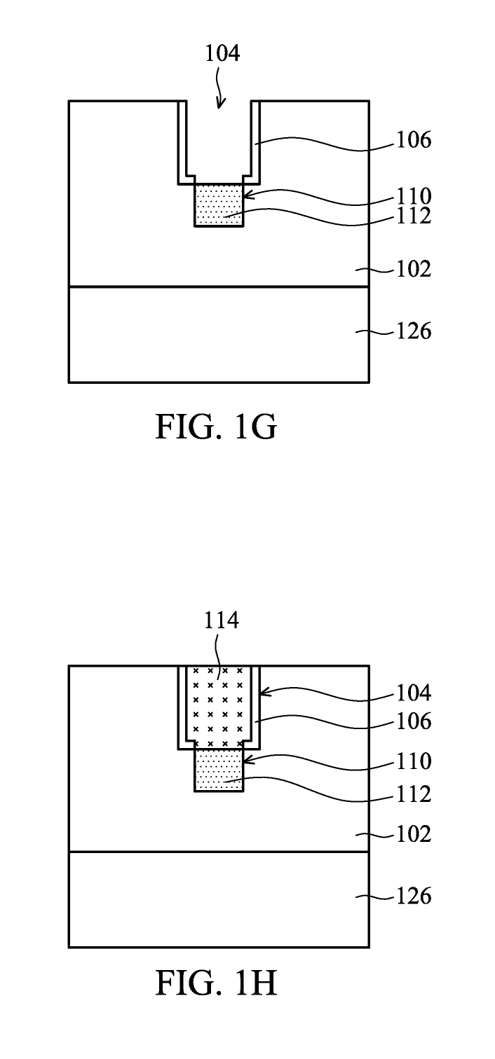

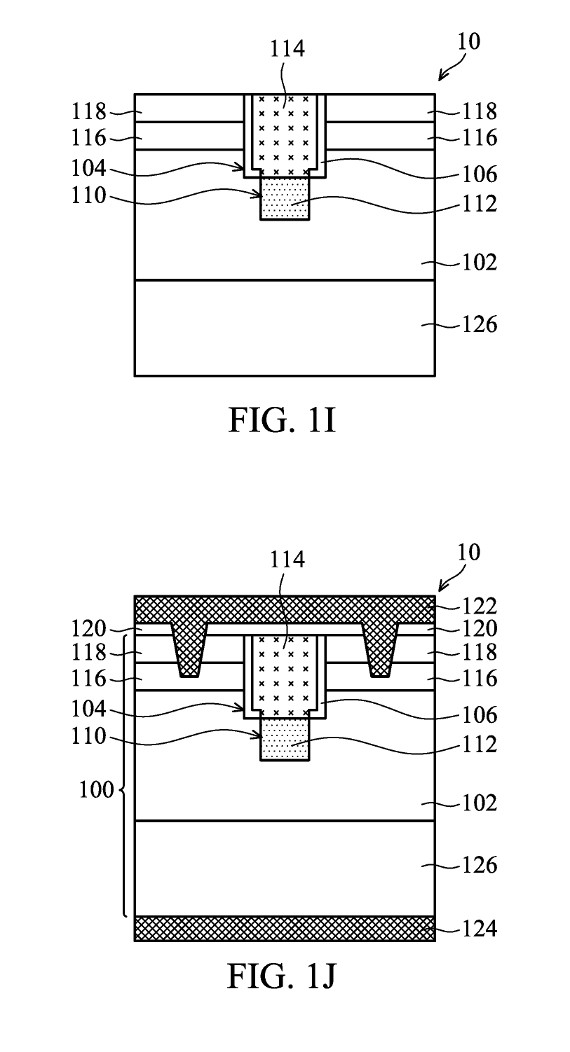

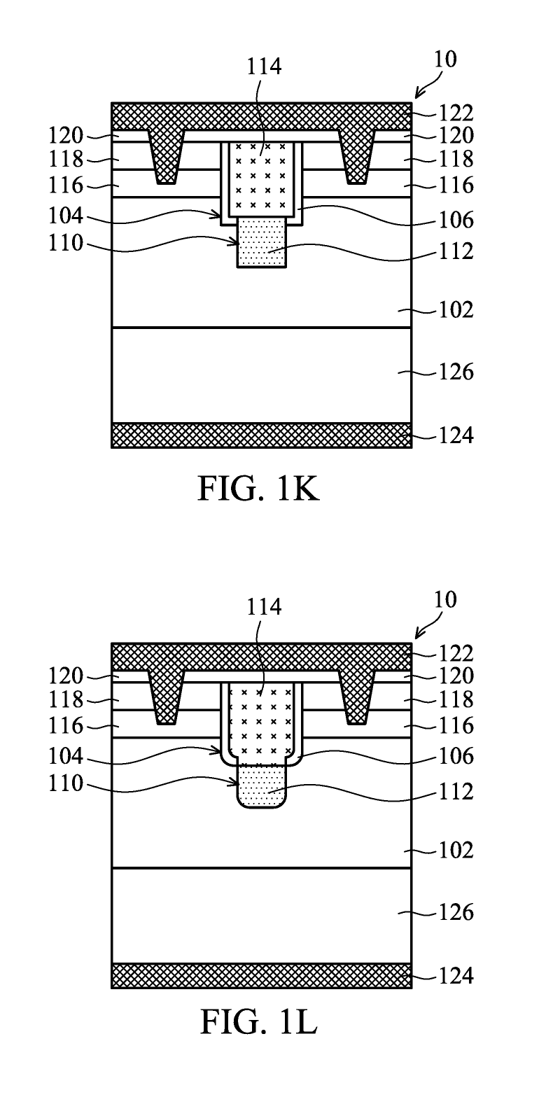

FIG. 1A illustrates an initial step of the present embodiment. First, a semiconductor substrate 100 is provided. The semiconductor substrate 100 may include an epitaxial region 102 and a portion 126 under the epitaxial region 102. In some embodiments, a doping concentration (e.g., in a range between 1×10¹⁸ and 1×10²⁰ cm⁻³) of the portion 126 of the semiconductor substrate 100 is greater than a doping concentration (e.g., in a range between 1×10¹⁵ and 1×10¹⁷ cm⁻³) of the epitaxial region 102. For example, the semiconductor substrate 100 may include silicon. In some other embodiments, the semiconductor substrate 100 may include other elementary semiconductors (e.g., germanium), compound semiconductors (e.g., silicon carbide (SiC), gallium arsenic (GaAs), indium arsenide (InAs), or indium phosphide (InP)), or alloy semiconductors (e.g., silicon germanium (SiGe), silicon germanium carbide (SiGeC), gallium arsenic phosphide (GaAsP), or gallium indium phosphide (GaInP)). For example, the epitaxial region 102 may be formed using a vapor phase epitaxy (VPE) method, a molecular-beam epitaxy (MBE) method, a metal organic chemical vapor deposition (MOCVD) method, a combination thereof, or other applicable methods. For example, the semiconductor substrate 100 may be an n-type substrate or a p-type substrate. For the interest of clarity, an n-type field-effect transistor formed in an n-type semiconductor substrate 100 is used as an example to discuss the present embodiment. However, one skilled in the art should understand that a p-type field-effect transistor may be formed in a p-type semiconductor substrate 100 in other embodiments of the present disclosure.

Then, still referring to FIG. 1A, a first dielectric layer 128 and a second dielectric layer 130 are formed on the epitaxial region 102. For example, the first dielectric layer 128 may include silicon oxide, other applicable dielectric materials, or a combination thereof. The first dielectric layer 128 may be formed by a chemical vapor deposition (CVD) method, a thermal oxidation method, other applicable methods, or a combination thereof. For example, the second dielectric layer 130 may include silicon nitride, other applicable dielectric materials, or a combination thereof. In some embodiments, the second dielectric layer 130 may be formed by a low pressure chemical vapor deposition (LPCVD) method, a plasma enhanced chemical vapor deposition (PECVD) method, other applicable methods, or a combination thereof.

In some embodiments, the first dielectric layer 128 may be a pad oxide layer formed of oxide, and the second dielectric layer 130 may be a pad nitride layer formed of nitride.

Then, referring to FIG. 1B, a gate trench 104 is formed in the epitaxial region 102 of the semiconductor substrate 100. For example, a patterned photoresist and/or a patterned hard mask (not shown in the figure) having an opening pattern corresponding to the gate trench 104 may be formed on the second dielectric layer 130 and the first dielectric layer 128, and then one or more etching processes may be performed using the patterned photoresist and/or the patterned hard mask as an etching mask(s) to form openings corresponding to the gate trench 104 in the second dielectric layer 130 and the first dielectric layer 128. Then, the patterned photoresist and/or the patterned hard mask may be removed. Then, an etching process may be performed using the second dielectric layer 130 and the first dielectric layer 128 as an etching mask(s) to form the gate trench 104 in the epitaxial region 102. For example, the etching process may be a dry etching process (e.g., an anisotropic plasma etching process), a wet etching process, or a combination thereof. In some embodiments, a dry etching process is used, which may be advantageous for forming the gate trench 104 with high aspect ratio.

Then, referring to FIG. 1C, a first conformal dielectric layer 106 is formed in the gate trench 104 to cover sidewalls and the bottom of the gate trench 104. For example, the first conformal dielectric layer 106 may include silicon oxide, silicon oxynitride, La₂O₃, Al₂O₃, HfO₂, HfON, ZrO₂, TaSiOₓ, other applicable materials, or a combination thereof. The first conformal dielectric layer 106 may be formed using an atomic-layer deposition (ALD) method, a molecular beam deposition (MBD) method, a chemical vapor deposition (CVD) method, a thermal oxidation method, other applicable methods, or a combination thereof. It should be noted that the first conformal dielectric layer 106 covering the sidewalls of the gate trench 104 may serve as the gate dielectric layer of the semiconductor structure to be formed. Therefore, the conformal dielectric layer 106 covering the sidewalls of the gate trench 104 may be designed to have an applicable thickness T depending on the desired properties of the field-effect transistor to be formed. For example, the thickness T of the first conformal dielectric layer 106 covering the sidewalls of the gate trench 104 may be in a range of 50 Å and 800 Å.

Then, still referring to FIG. 1C, a second conformal dielectric layer 108 is formed on the first conformal dielectric layer 106. The second conformal dielectric layer 108 may have a portion 108A on the second dielectric layer 130, a portion 108B on the sidewalls of the gate trench 104, and a portion 108C on the bottom of the gate trench 104. In some embodiments, a thickness T′ of the second conformal dielectric layer 108 may be in a range between 3 μm and 10 μm. For example, the second conformal dielectric layer 108 may include silicon nitride, silicon oxynitride, or other applicable materials. In some embodiments, the second conformal dielectric layer 108 may be formed by a low pressure chemical vapor deposition (LPCVD) method, a plasma enhanced chemical vapor deposition (PECVD) method, other applicable methods, or a combination thereof.

Then, as shown in FIG. 1D, an etching process (e.g., a dry etching process) may be performed to remove the portion 108A and the portion 108C of the second conformal dielectric layer 108, such that a portion of the first conformal dielectric layer 106 covering the bottom of the gate trench 104 is exposed. As shown in FIG. 1D, the portion 108B is substantially not removed by the etching process, or is only slightly removed by the etching process. Therefore, the portion 108B of the second conformal dielectric layer 108 remains on the sidewalls of the gate trench 104 after the etching process. In some embodiments, the second conformal dielectric layer 108 may include a material different from that of the first conformal dielectric layer 106 (e.g., the first conformal dielectric layer 106 may be made of an oxide, and the second conformal dielectric layer 108 may be made of a nitride). Therefore, in a subsequent etching process, the remaining portion 108B of the second conformal dielectric layer 108 may be used as an etch mask to etch the first conformal dielectric layer 106 and the semiconductor substrate 100 to form a gate trench extending portion 110 (as shown in FIG. 1E). The details will be discussed below.

Then, referring to FIG. 1E, the gate trench 104 may be recessed to form a gate trench extending portion 110 under the gate trench 104. As discussed above, in some embodiments, one or more etching processes using the remaining portion 108B of the second conformal dielectric layer 108 as an etch mask may be performed to etch the first conformal dielectric layer 106 on the bottom of the gate trench 104, and then etch the epitaxial region 102 of the semiconductor substrate 100 to form the gate trench extending portion 110. Therefore, no additional photo mask is needed, and thus the cost can be reduced. For example, the etching process may be a dry etching process (e.g., an anisotropic plasma etching process), a wet etching process, or a combination thereof. In some embodiments, as shown in FIG. 1E, the width of the gate trench extending portion 110 is less than the width of the gate trench 104.

Then, as shown in FIG. 1F, an insulating stud 112 may be formed in the gate trench extending portion 110. For example, the insulating stud 112 may include an oxide, a nitride, an oxynitride, other applicable materials, or a combination thereof. In some embodiments, a local oxidation process is performed to form an insulating stud 112 of an oxide in the gate trench extending portion 110. It should be noted that if the first conformal dielectric layer 106 is also oxidized in the local oxidation process, the oxidation of the first conformal dielectric layer 106 may change the thickness of the first conformal dielectric layer 106, and thus the first conformal dielectric layer 106 may be unable to maintain the designed thickness depending on the desired properties of the field-effect transistor to be formed. Therefore, in some embodiments, the remaining portion 108B of the second conformal dielectric layer 108 may be used as an oxidation mask to prevent the oxidation of the first conformal dielectric layer 106.

Then, as shown in FIG. 1G, one or more etching processes may be performed to remove the second dielectric layer 130, the second conformal dielectric layer 108, the first dielectric layer 128, and the first conformal dielectric layer 106 outside the gate trench 104. For example, the etching process may be a dry etching process (e.g., an anisotropic plasma etching process), a wet etching process, or a combination thereof. In some embodiments, a wet etching process may be performed to remove the second conformal dielectric layer 108, and a dry etching process may be performed to remove the second dielectric layer 130, the first dielectric layer 128, and the first conformal dielectric layer 106 outside the gate trench 104. In some other embodiments, a chemical mechanical polishing (CMP) process may also be used, and the gate trench 104 may be filled with removable materials (e.g., photoresist) to protect the first conformal dielectric layer 106 in the gate trench 104 and the insulating stud 112 in the gate trench extending portion 110.

Then, as shown in FIG. 1H, a gate electrode 114 may be formed in the gate trench 104. For example, the gate electrode 114 may include poly-silicon, metals and/or the silicides thereof, other applicable conductive materials, or a combination thereof. In some embodiments, a chemical vapor deposition (CVD) method, a sputtering method, an electroplating method, a resistive heating evaporation method, an electron beam evaporation method, or other applicable deposition methods may be used to fill the gate trench 104 with applicable conductive materials to form the gate electrode 114. In addition, after depositing the conductive material, a chemical mechanical polishing process or an etch-back process may be optionally performed to remove the excess conductive material outside the gate trench 104.

Then, as shown in FIG. 1I, a doping well region 116 may be formed in the semiconductor substrate 100 at opposite sides of the gate trench 104. In the present embodiment, the semiconductor structure 10 to be formed is an n-type field-effect transistor, and thus the doping well region 116 is a p-type doping region. For example, an ion implantation process may be performed to implant boron ions, indium ions, or boron difluoride ions (BF2⁺) into the semiconductor substrate 100 at opposite sides of the gate trench 104 to form the p-type doping well region 116 having a doping concentration in a range between 1×10¹⁵ and 1×10¹⁸ cm⁻³. In other embodiments, the semiconductor structure to be formed is a p-type field-effect transistor, and thus the doping well region 116 is an n-type doping region. For example, an ion implantation process may be performed to implant phosphorous ions or arsenic ions into the semiconductor substrate 100 at opposite sides of the gate trench 104 to form the n-type doping well region 116 having a doping concentration in a range between 1×10¹⁵ and 1×10¹⁸ cm⁻³.

Then, a source region 118 may be formed in the semiconductor substrate 100 on the doping well region 116 to form the semiconductor structure 10. In the present embodiment, the semiconductor structure 10 is an n-type field-effect transistor, and thus the source region 118 is an n-type doping region. For example, an ion implantation process may be performed to implant phosphorous ions or arsenic ions into the semiconductor substrate 100 on the doping well region 116 to form the n-type source region 118 having a doping concentration in a range between 1×10¹⁹ and 1×10²¹ cm⁻³. In other embodiments, the semiconductor structure is a p-type field-effect transistor, and thus the source region 118 is a p-type doping region. For example, an ion implantation process may be performed to implant boron ions, indium ions, or boron difluoride ions (BF2⁺) into the semiconductor substrate 100 on the doping well region 116 to form the p-type source region 118 having a doping concentration in a range between 1×10¹⁹ and 1×10²¹ cm⁻³.

As shown in FIG. 1I, the semiconductor structure 10 of the embodiment of the present disclosure includes the insulating stud 112 formed under the gate electrode 114. Therefore, the breakdown voltage of the semiconductor structure 10 can be increased without affecting its on-resistance and threshold voltage.

Then, as shown in FIG. 1J, an insulating layer 120 and a source contact 122 may be optionally formed on the semiconductor substrate 100. In some embodiments, the source contact 122 may be electrically connected to the source region 118 and the doping well region 116 to avoid the turning on of the parasitic bipolar transistor which may affect the performance of the device. For example, the source contact 122 may include a metal (e.g., W, Al, or Cu), or other applicable conductive materials.

In should be noted that the semiconductor substrate 100 under the insulating stud 112 may serve as a drain region of the semiconductor structure 10. In addition, as shown in FIG. 1J, a drain contact 124 may be optionally formed below the semiconductor 100. For example, the drain contact 124 may include a metal (e.g., W, Al, or Cu), or other applicable conductive materials.

In the present embodiment, the insulating stud 112 is formed in the gate trench extending portion 110. However, in some other embodiments, as shown in FIG. 1K, the insulating stud 112 may be further formed in the bottom of the gate trench 104. Therefore, the electric filed may be further relieved to extend the area of the depletion region, and thus the breakdown voltage of the device may be further increased.

In the present embodiment, each of the gate trench 104 and the gate trench extending portion 110 has substantially straight sidewalls. However, in other embodiments, the etching parameters may be properly controlled so that each of the gate trench 104 and the gate trench extending portion 110 may have arc sidewalls that taper downward (as shown in FIG. 1L) to avoid the problem of non-uniform distribution of the electric field.

Various variations of the embodiments of the present disclosure will be discussed below. For the interest of simplicity and clarity, like reference numerals may be used to represent like elements. In addition, the reference numerals and/or letters may be repeated in various embodiments. This repetition is for the purpose of simplicity and clarity and does not in itself dictate a relationship between the various embodiments and/or configurations discussed.

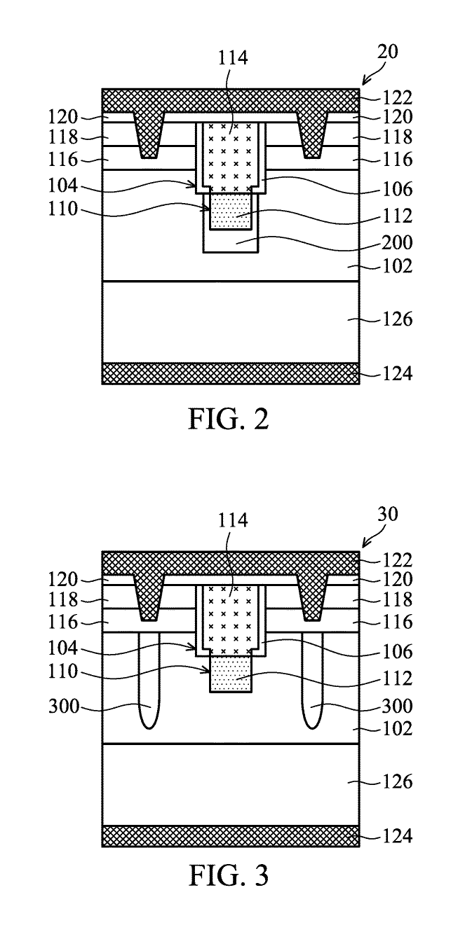

Then, referring to FIG. 2, it illustrates a semiconductor structure 20 of another embodiment of the present disclosure. One difference between the semiconductor structure 20 and the semiconductor structure 10 is that the semiconductor structure 20 further includes a counter-doping region 200 surrounding the insulating stud 112, and thus the breakdown voltage may be further increased. The conductive type of the counter-doping region 200 may be the same as the conductive type of the semiconductor substrate 100, and the doping concentration of the counter-doping region 200 may be lower than the doping concentration of the epitaxial region 102 of the semiconductor substrate 100. For example, a ratio of the doping concentration of the epitaxial region 102 of the semiconductor substrate 100 to the doping concentration of the counter-doping region 200 may be in a range between 2 and 8 (e.g., in a range between 4 and 6). For example, after forming the gate trench extending portion 110 (as shown in FIG. 1E) and before forming the insulating stud 112, an ion implantation process using the remaining portion 108B of the second conformal dielectric layer 108 and the second dielectric layer 130 as a mask may be performed to form the counter-doping region 200. In some embodiments where the semiconductor structure 20 is an n-type field-effect transistor, p-type dopants (e.g., boron ions, indium ions, or boron difluoride ions (BF2⁺)) may be implanted into a portion of the epitaxial region 102 of the n-type semiconductor substrate 100 surrounding the insulating stud 112, so that the doping concentration of the portion of the epitaxial region 102 of the n-type semiconductor substrate 100 surrounding the insulating stud 112 may be reduced to form the counter-doping region 200. In some embodiments where the semiconductor structure 20 is a p-type field-effect transistor, n-type dopants (e.g., phosphorous ions or arsenic ions) may be implanted into a portion of the epitaxial region 102 of the p-type semiconductor substrate 100 surrounding the insulating stud 112, so that the doping concentration of the portion of the epitaxial region 102 of the p-type semiconductor substrate 100 surrounding the insulating stud 112 may be reduced to form the counter-doping region 200.

Then, referring to FIG. 3, it illustrates a semiconductor structure 30 of an embodiment of the present disclosure. One difference between the semiconductor structure 30 and the semiconductor structure 10 is that the semiconductor structure 30 further includes a reduced surface field doping region 300 formed in the semiconductor substrate 100 at opposite sides of the insulating stud 112, and thus the breakdown voltage can be further increased. The conductive type of the reduced surface field doping region 300 may be opposite to the conductive type of the semiconductor substrate 100. For example, before forming the source contact 122, dopants may be implanted into the semiconductor substrate 100 at opposite sides of the insulating stud 112 to form the reduced surface field doping region 300. In some embodiments where the semiconductor structure 30 is an n-type field-effect transistor, p-type dopants (e.g., boron ions, indium ions, or boron difluoride ions (BF2⁺)) may be implanted into the n-type semiconductor substrate 100 at opposite sides of the insulating stud 112 to form the p-type reduced surface field doping region 300. In some embodiments where the semiconductor structure 30 is a p-type field-effect transistor, n-type dopants (e.g., phosphorous ions or arsenic ions) may be implanted into the p-type semiconductor substrate 100 at opposite sides of the insulating stud 112 to form the n-type reduced surface field doping region 300.

In summary, the semiconductor structure of the embodiments of the present disclosure includes the insulating stud formed under the gate electrode to increase the breakdown voltage. In addition, the semiconductor structure of the embodiments of the present disclosure may further include the counter-doping region and/or the reduced surface field doping region, and thus the breakdown voltage may be further increased.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a semiconductor substrate;
a gate trench in the semiconductor substrate;
a gate dielectric layer disposed on sidewalls of the gate trench;
a gate trench extending portion under the gate trench;
an insulating stud disposed in the gate trench extending portion;
a gate electrode disposed in the gate trench and on the insulating stud;
a doping well region embedded in the semiconductor substrate at opposite sides of the gate trench; and
a source region disposed on the doping well region in the semiconductor substrate,
wherein the insulating stud has an upper surface and a bottom surface, the upper surface and the bottom surface of the insulating stud are substantially flat, and an area of the upper surface is substantially equal to an area of the bottom surface.

2. The semiconductor structure of claim 1, further comprising:
a drain region disposed in the semiconductor substrate under the insulating stud.

3. The semiconductor structure of claim 1, wherein a width of the gate trench extending portion is less than a width of the gate trench.

4. The semiconductor structure of claim 1, wherein the semiconductor substrate and the source region have a first conductive type, and the doping well region has a second conductive type opposite to the first conductive type.

5. The semiconductor structure of claim 4, wherein the first conductive type is n-type, and the second conductive type is p-type.

6. The semiconductor structure of claim 4, further comprising:
a reduced surface field (RESURF) doping region formed in the semiconductor substrate at opposite sides of the insulating stud, wherein the reduced surface field doping region has the second conductive type.

7. The semiconductor structure of claim 4, further comprising:
a counter-doping region disposed in the semiconductor substrate and covering a side surface and the bottom surface of the insulating stud, wherein the counter-doping region has the first conductive type.

8. The semiconductor structure of claim 7, wherein a doping concentration of the counter-doping region is less than a doping concentration of the semiconductor substrate.

9. The semiconductor structure of claim 1, wherein the insulating stud comprises an oxide, a nitride, an oxynitride, or a combination thereof.

10. The semiconductor structure of claim 1, wherein the insulating stud is further disposed in a bottom of the gate trench.

11. A method of forming a semiconductor structure, comprising:
providing a semiconductor substrate;
forming a gate trench in the semiconductor substrate;
forming a gate dielectric layer on sidewalls of the gate trench;
recessing the gate trench to form a gate trench extending portion under the gate trench;
forming an insulating stud in the gate trench extending portion;
forming a gate electrode in the gate trench and on the insulating stud;
forming a doping well region in the semiconductor substrate at opposite sides of the gate trench; and
forming a source region on the doping well region in the semiconductor substrate.

12. The method of forming a semiconductor structure of claim 11, wherein the step of forming the gate trench extending portion comprises:
forming a first conformal dielectric layer to cover the sidewalls and a bottom of the gate trench;
forming a second conformal dielectric layer on the first conformal dielectric layer, wherein the second conformal dielectric layer exposes a portion of the first conformal dielectric layer covering the bottom of the gate trench; and
etching the first conformal dielectric layer and the semiconductor substrate by using the second conformal dielectric layer as an etch mask to form the gate trench extending portion under the gate trench.

13. The method of forming a semiconductor structure of claim 12, wherein the insulating stud comprises an oxide, a nitride, an oxynitride, or a combination thereof.

14. The method of forming a semiconductor structure of claim 13, wherein the step of forming the oxide comprises:
performing a local oxidation process by using the second conformal dielectric layer as a mask.

15. The method of forming a semiconductor structure of claim 12, further comprising:
removing the second conformal dielectric layer after forming the insulating stud and before forming the gate electrode.

16. The method of forming a semiconductor structure of claim 12, further comprising:
forming a counter-doping region in the semiconductor substrate and surrounding the insulating stud, wherein the counter-doping region has a first conductive type which is the same as a conductive type of the semiconductor substrate, and a doping concentration of the counter-doping region is less than a doping concentration of the semiconductor substrate.

17. The method of forming a semiconductor structure of claim 16, wherein the step of forming the counter-doping region comprises:
performing an implantation process by using the second conformal dielectric layer as a mask to dope dopants having a second conductive type opposite to the first conductive type of the semiconductor substrate into a portion of the semiconductor substrate surrounding the insulating stud to lower a doping concentration of the portion of the semiconductor substrate surrounding the insulating stud, whereby the counter-doping region is formed.

18. The method of forming a semiconductor structure of claim 17, wherein the implantation process is performed before forming the insulating stud.
